(19) United States
(12) Patent Application Publication
(10) Pub. No.: US 2025/0323010 A1
(43) Pub. Date: Oct. 16, 2025

(54) MULTI CHARGED PARTICLE BEAM IRRADIATION APPARATUS AND ADJUSTING METHOD THEREOF

(71) Applicant: NuFlare Technology, Inc., Yokohama-shi (JP)

(72) Inventors: Munehiro OGASAWARA, Hiratsuka-shi (JP); Hirofumi MORITA, Setagaya-ku (JP); Takanao TOUYA, Kawasaki-shi (JP)

(73) Assignee: NuFlare Technology, Inc., Yokohama-shi (JP)

(21) Appl. No.: 19/095,136

(22) Filed: Mar. 31, 2025

(30) Foreign Application Priority Data
Apr. 10, 2024 (JP) 2024-063475

(51) Int. Cl. H01J 37/21; H01J 37/12; H01J 37/141

(52) U.S. Cl. CPC H01J 37/21; H01J 37/12; H01J 37/141; H01J 2237/0435; H01J 2237/04922

(57) ABSTRACT

In one embodiment, a multi charged particle beam irradiation apparatus includes an optical system including three or more focus correcting lenses configured to adjust multiple beams, and a lens control circuit. A virtual crossover as viewed from a downstream side of the multiple beams is formed in an anterior focal plane of a lowermost objective lens. The multiple beams are perpendicularly incident on the sample surface. An actual crossover (CO2r) is located between a principal surface of an uppermost focus correcting lens and a principal surface of a lowermost focus correcting lens. The lens control circuit is configured to control a voltage applied to or a current passed through each of the focus correcting lenses such that a predetermined rotation angle condition, a condition under which a virtual crossover (CO2) as viewed from the downstream side is unchanged, and an in-focus condition are satisfied.

### CROSS REFERENCE TO RELATED APPLICATION

This application is based upon and claims benefit of priority from the Japanese Patent Application No. 2024-063475, filed on Apr. 10, 2024, the entire contents of which are incorporated herein by reference.

### FIELD

The present invention relates to a multi charged particle beam irradiation apparatus and an adjusting method thereof.

### BACKGROUND

In recent years, along with high integration of LSI, the circuit line width required for semiconductor devices has been reduced year by year. Here, the electron ray (electron beam) writing technique essentially has an excellent resolution, and a mask pattern is written to a mask blank with an electron beam.

For example, there is a writing apparatus using a multi-beam. Compared to a single electron beam writing, many beams can be irradiated at one time using a multi-beam, thus the throughput can be significantly improved. In a multi-beam writing apparatus, for example, an electron beam emitted from an electron gun is passed through an aperture array substrate having a plurality of openings to form a multi-beam which is each blanking-controlled, and each beam not blocked by a stopping plate is reduced by an optical system, and deflected by a deflector, then applied to a desired position on a sample.

In an example of an optical system of related art, a crossover is formed in a focal plane in front of an objective lens (i.e., upstream of the objective lens in a beam propagation direction), so that beams are perpendicularly incident on a sample surface. When beams are perpendicularly incident on the sample surface, a beam array distribution does not change even if the height of the sample surface changes. When the objective lens is an electromagnetic lens and a magnetic field is present on the sample surface, a slight deviation in the rotation direction occurs. However, if the deviation is within an allowable range, the incidence is considered perpendicular.

When the half-angle of beam convergence is increased to increase a current of each beam of multiple beams, the size of beam blur will increase if the height of the sample surface changes. To suppress beam blur, it is necessary to change the excitation of the objective lens to perform focus correction and adjust the image height to the height of the sample surface. However, the beam array distribution of multiple beams changes as the excitation changes. When the current of multiple beams changes, defocus occurs due to the Coulomb effect. Although it is effective to perform focus correction of the objective lens to correct the effect of the defocus, the same problem as above occurs.

### BRIEF DESCRIPTION OF THE DRAWINGS

FIG. 1 is a diagram schematically illustrating a configuration of a multi-beam writing apparatus according to an embodiment of the present invention.

FIG. 2 is a schematic diagram of a shaping aperture array substrate.

FIG. 3 is a diagram for explaining a crossover.

FIG. 4 is a diagram illustrating an example of focus correction.

FIG. 5 is a schematic diagram of a modified focus correcting lens.

### DETAILED DESCRIPTION

In one embodiment, a multi charged particle beam irradiation apparatus includes a charged particle source configured to generate and emit multiple beams, an optical system including a plurality of lenses configured to adjust the multiple beams emitted from the charged particle source, and a lens control circuit configured to control the plurality of lenses. The optical system is configured such that a virtual crossover as viewed from a downstream side of the multiple beams is formed in an anterior focal plane of an objective lens being a lowermost lens of the plurality of lenses, the anterior focal plane being located opposite a sample surface with respect to the objective lens, and that the multiple beams passed through the objective lens are perpendicularly incident on the sample surface. The plurality of lenses include three or more focus correcting lenses configured to perform focus correction of the multiple beams in accordance with a height of the sample surface and/or beam current. An actual crossover (CO2r) is located between a principal surface of an uppermost focus correcting lens of the three or more focus correcting lenses and a principal surface of a lowermost focus correcting lens of the three or more focus correcting lenses. The lens control circuit is configured to control a voltage applied to or a current passed through each of the focus correcting lenses such that a predetermined rotation angle condition, a condition under which a virtual crossover (CO2) as viewed from the downstream side is unchanged, and an in-focus condition are satisfied.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

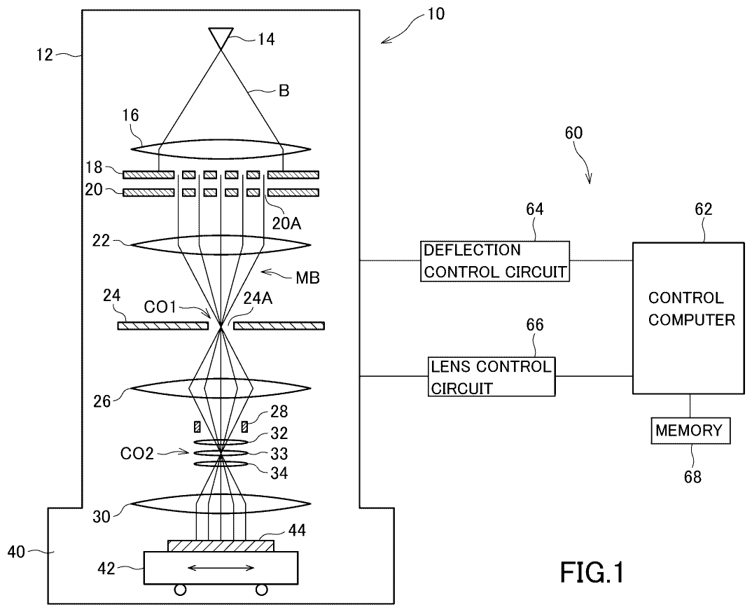

A writing apparatus illustrated in FIG. 1 includes a writer 10 configured to write a desired pattern by irradiating a sample, such as a mask or a wafer, with an electron beam, and a controller 60 configured to control the operation of the writer 10. The writer 10 includes an electron optical column 12 and a writing chamber 40. In the present embodiment, a multi-beam writing apparatus will be described as an example of the multi-beam irradiation apparatus.

The electron optical column 12 includes an electron source 14, an illuminating lens 16, a shaping aperture array substrate 18, a blanking aperture array substrate 20, a projection lens 22, a stopping aperture member (limiting aperture member) 24, a first objective lens 26, a positioning deflector 28, a second objective lens 30, and three focus correcting lenses 32 to 34. The writing chamber 40 includes an XY stage 42. A sample 44, such as a mask blank, on which writing is to be performed is placed on the XY stage 42. The multi-beam writing apparatus is configured to irradiate the sample 44 with multiple beams by using an optical system including a plurality of lenses, such as the illuminating lens 16, the projection lens 22, the first objective lens 26, the second objective lens 30, and the three focus correcting lenses 32 to 34.

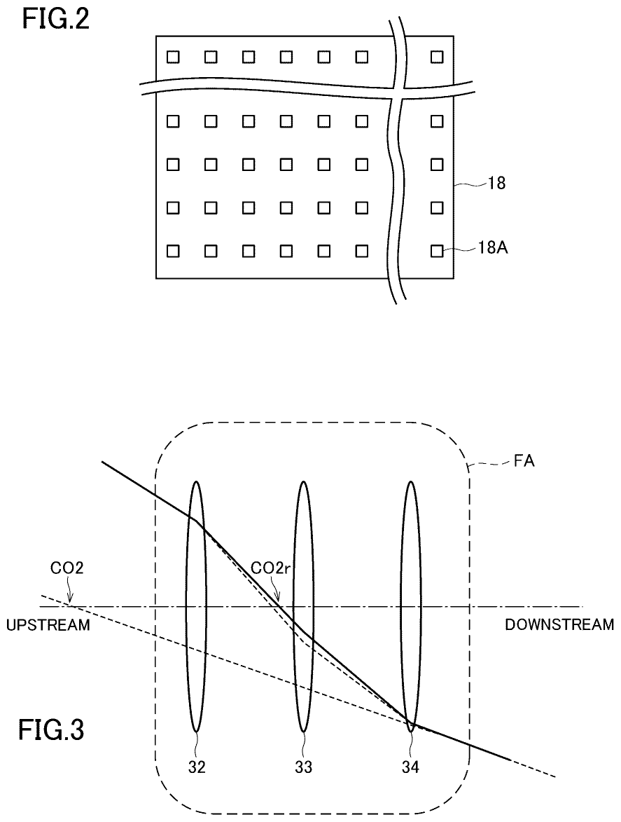

As illustrated in FIG. 2, the shaping aperture array substrate 18 has m columns by n rows (m, n≥2) of openings (first openings) 18A arranged at a predetermined array pitch. The openings 18A are of the same rectangular shape and dimensions. The openings 18A may be circular. These openings 18A each allow part of an electron beam B to pass through to form multiple beams MB.

A sample surface height measuring unit (not illustrated) is provided. Examples of the sample surface height measuring unit include a sample surface height measuring device of an optical lever type configured to measure the sample surface height using reflected light obtained by irradiating a region including an electron beam irradiation position on the sample surface. With this device, the height of a position at which the sample surface is irradiated with electron beams can be determined.

A Faraday cup (not illustrated) is disposed on the XY stage 42, so that beam current can be measured.

The blanking aperture array substrate 20 is disposed below the shaping aperture array substrate 18. The blanking aperture array substrate 20 has passage holes 20A (second openings) corresponding to the respective openings 18A in the shaping aperture array substrate 18. A blanker (not illustrated) composed of a pair of electrodes is disposed in each of the passage holes 20A. One electrode of the blanker is fixed at a ground potential, and the other electrode of the blanker is switched between the ground potential and a potential different from the ground potential. An electron beam passing through each passage hole 20A is independently deflected by a voltage applied to the blanker. A plurality of blankers thus perform blanking deflection of corresponding beams of the multiple beams MB passed through the openings 18A in the shaping aperture array substrate 18.

The stopping aperture member 24 is configured to block beams deflected by the blankers. Beams not blocked by the blankers pass through an opening 24A (third opening) in the center of the stopping aperture member 24. To reduce beam leakage during individual blanking performed by the blanking aperture array substrate 20, the stopping aperture member 24 is disposed in an image plane of a crossover (virtual source image) CO1 where the spread of beams is reduced.

The controller 60 includes a control computer 62, a deflection control circuit 64, a lens control circuit 66, and a memory 68. The deflection control circuit 64 is configured to control the blankers in the blanking aperture array substrate 20, and a voltage applied to electrodes of the positioning deflector 28. The lens control circuit 66 is configured to control a voltage applied to the illuminating lens 16, the projection lens 22, the first objective lens 26, the second objective lens 30, and the focus correcting lenses 32 to 34.

With the electron beam B emitted from the electron source 14, the illuminating lens 16 substantially perpendicularly illuminates the entire shaping aperture array substrate 18. The electron beam B passes through the openings 18A in the shaping aperture array substrate 18 to form the multiple beams MB composed of electron beams. The multiple beams MB pass through corresponding blankers in the blanking aperture array substrate 20.

After passing through the blanking aperture array substrate 20, the multiple beams MB are reduced in size by the projection lens 22 and propagate toward the opening 24A in the center of the stopping aperture member 24 to form the crossover CO1. The electron beams deflected by the blankers of the blanking aperture array substrate 20 are off the position of the opening 24A in the stopping aperture member 24 and are blocked by the stopping aperture member 24. On the other hand, the electron beams not deflected by the blankers pass through the opening 24A in the stopping aperture member 24. Blanking control is performed by turning on and off the blankers, so that beams are controlled to turn on and off.

The stopping aperture member 24 is thus configured to block each of beams that have been deflected by the blankers of the blanking aperture array substrate 20 in such a way that the beams are turned off.

After passing through the stopping aperture member 24, the multiple beams MB are brought into focus by the first objective lens 26, the second objective lens 30, and the focus correcting lenses 32 to 34 to form a pattern image with a desired reduction ratio, which is applied onto the sample 44.

Specifically, after passing through the stopping aperture member 24, the multiple beams MB are reduced in size by the first objective lens 26 to form a virtual crossover CO2 as viewed from a downstream side, in an anterior focal plane of the second objective lens 30. Here, the anterior focal plane of the second objective lens 30 is a focal plane located opposite the sample 44 as viewed from the second objective lens 30, or in other words, a focal plane located upstream of the second objective lens 30 in the beam propagation direction. After forming the virtual crossover CO2 as viewed from a downstream side in the anterior focal plane of the second objective lens 30, the multiple beams MB are refracted by the second objective lens 30 to be parallel with the optical axis and are perpendicularly incident on the sample 44.

The second objective lens 30 is the lowermost lens of the plurality of lenses included in the optical system.

The positioning deflector 28 disposed between the first objective lens 26 and the second objective lens 30 is configured to deflect the multiple beams MB and irradiate, with the multiple beams MB, the sample 44 on the continuously moving XY stage 42 at a desired position. The positioning deflector 28 includes a plurality of electrodes. For example, a quadrupole deflector including four electrodes or an octupole deflector including eight electrodes can be used. By varying a voltage applied to each electrode of the positioning deflector 28, the beam deflection position (i.e., beam irradiation position on the sample 44) can be changed. The positioning deflector 28 may be disposed downstream of the focus correcting lens 34. For example, the positioning deflector 28 may be disposed in the second objective lens 30.

The three focus correcting lenses 32 to 34 are disposed between the second objective lens 30 and the positioning deflector 28. For example, the focus correcting lenses 32, 33, and 34 are arranged in this order in the direction from the positioning deflector 28 toward the second objective lens 30 (i.e., along the beam propagation direction). Hereinafter, the focus correcting lens 32 will also be referred to as an upper (uppermost) focus correcting lens, the focus correcting lens 33 will also be referred to as a middle focus correcting lens, and the focus correcting lens 34 will also be referred to as a lower (lowermost) focus correcting lens.

In the present embodiment, the focus correcting lenses 32 to 34 are arranged in such a way that a virtual crossover position as viewed from the downstream side, corresponding to the anterior focal plane of the second objective lens 30 (or its conjugate point), is located at a height between the principal surface of the upper focus correcting lens 32 and the principal surface of the lower focus correcting lens 34. Note that the virtual crossover position as viewed from the downstream side refers to a crossover position obtained by tracing the trajectory back from the downstream side of a focus correcting mechanism and assuming that there is no electromagnetic field at the position of the focus correcting mechanism. In contrast, when simply referred to as a crossover position, it means a position where a paraxial trajectory passes across the optical axis. When there is no electromagnetic field near the crossover, such as when the focus correcting mechanism does not exist, the paraxial trajectory that gives a crossover is straight near the crossover position, and the virtual crossover position as viewed from the downstream side coincides with the crossover position.

The focus correcting lenses 32 to 34 are non-rotating lenses. For example, electrostatic lenses, such as electrostatic einzel lenses, can be used as the focus correcting lenses 32 to 34. Voltages applied to the focus correcting lenses 32 to 34 and satisfying a non-rotating condition, a condition under which the virtual crossover CO2 as viewed from the downstream side is unchanged, and an in-focus condition (i.e., condition under which an image of the shaping aperture array substrate 18 is formed on the sample surface) are determined in advance by experiment or simulation. Then, a table that defines the voltages to be applied is stored in the memory 68.

The virtual crossover CO2 as viewed from the downstream side being unchanged means that when, as illustrated in FIG. 3, a trajectory corresponding to the image of the virtual crossover CO2 as viewed from the downstream side enters a focus correcting mechanism FA, the virtual crossover CO2 as viewed from the downstream side after a focus correcting operation performed downstream of the focus correcting mechanism FA coincides with that before the focus correcting operation within a range of required accuracy. That is, the virtual crossover position obtained by tracing the trajectory back from the downstream side of the focus correcting mechanism FA (virtual crossover position as viewed from the downstream side) does not change within a range of required accuracy.

In contrast, a position defined as a point where the trajectory corresponding to the image of the virtual crossover CO2 as viewed from the downstream side passes across the optical axis after entering the focus correcting mechanism FA, is referred to as an actual crossover, which is denoted by CO2r. The actual crossover CO2r is located inside the focus correcting mechanism FA. The virtual crossover CO2 as viewed from the downstream side may be located either outside or inside the focus correcting mechanism FA.

An allowable variation in crossover position is determined from an allowable variation in the magnification of multiple beams. In this example, the focus correcting mechanism FA includes the focus correcting lenses 32 to 34. The focus correcting mechanism FA is defined as a region where the electromagnetic field of the focus correcting lenses 32 to 34 is strong enough to have an effect on the trajectory. The boundary of the focus correcting mechanism FA is determined in such a way that outside the boundary, the trajectory of the electron beam can be approximated to a straight line. When an einzel lens is used as the focus correcting lenses 32 to 34 and the lens electric field is negligible outside the grounded aperture, the outer edge of an external ground aperture can be defined as the boundary of the focus correcting mechanism FA. When magnetic lenses are used as the focus correcting lenses 32 to 34, if leakage of the aperture lens magnetic field at the outer edge of a region surrounded by a pole piece or a magnetic body is sufficiently small, the opening at the outer edge can be defined as the boundary of the focus correcting mechanism FA.

The lens control circuit 66 refers to the table stored in the memory 68 and controls the voltages applied to the focus correcting lenses 32 to 34 on the basis of the surface height of the sample 44 detected by a Z sensor (not illustrated) to perform focus correction (dynamic focusing). If the amount of focus correction not listed in the table is required, an appropriate voltage can be determined, for example, by interpolating values listed in the table. For example, two pieces of data listed in the table may be interpolated, or a polynomial that can be obtained by fitting to multipoint data is determined, so that a lens control value can be obtained using the polynomial. Since excitation of the second objective lens 30 is not changed, a perpendicular incidence condition is maintained.

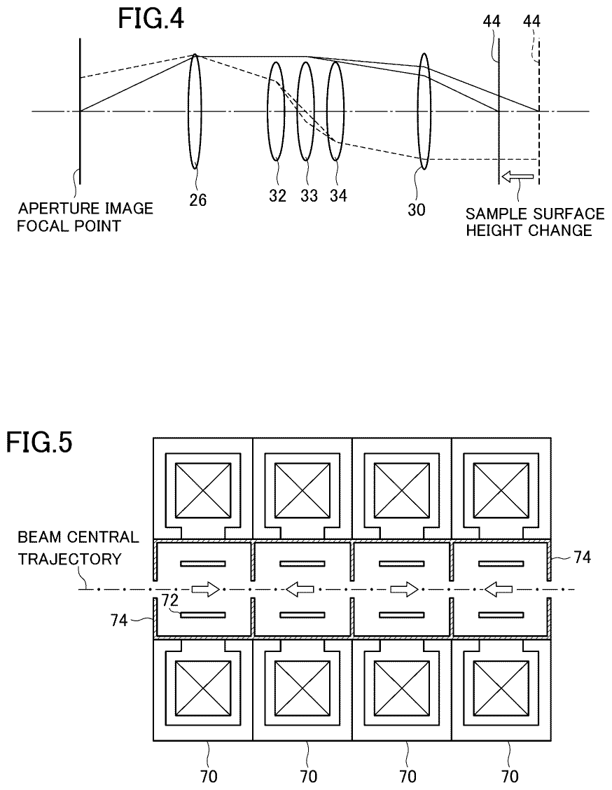

Thus, as illustrated in FIG. 4, it is possible to perform focus correction without changing the beam array distribution of the multiple beams and while maintaining the perpendicular incidence condition, and change the image height in accordance with the sample surface height. In FIG. 4, a solid line represents a central trajectory, and a broken line represents an off-axis trajectory. If the irradiation position of the entire multiple beams on the sample surface is changed by the focus correction, the positioning deflector 28 may make the correction.

In the embodiment described above, focus correction is performed when the sample surface height changes. Focus correction may also be required when a beam current significantly changes. In the multi-beam writing apparatus, the number of beams changes depending on the pattern to be written, and all beam currents applied to the sample surface change. When the beam current increases, Coulomb force between electrons forming an electron beam causes a phenomenon in which the electron beam expands. The resulting effect generally appears in the direction in which the image plane shifts downstream. Here, this is referred to as defocus caused by the Coulomb effect. To suppress defocus caused by the Coulomb effect, the lens focal length is adjusted to make correction such that the image plane is in the sample surface. Again, as described in the embodiment, an adjustment is made here such that the crossover position is unchanged and non-rotating. In this case, the values of all beam currents, not the height of the sample surface, are required, and the beam currents can be determined, for example, from blanker control signals for the blanking aperture array substrate 20. The focal length of the objective lens may be adjusted in accordance with the beam currents determined as described above. In this case, the lens control circuit 66 may also refer to the table stored in the memory 68 and control the voltages applied to the focus correcting lenses 32 to 34 on the basis of the beam currents to perform focus correction.

Both a change in sample surface height and a change in beam current may occur. Similarly to the above, tables corresponding to the conditions may be stored in the memory 68, so that voltages to be applied to the focus correcting lenses 32 to 34 are determined.

In the embodiment described above, three electrostatic lenses are used as the non-rotating lenses serving as the focus correcting lenses included in the focus correcting mechanism. However, four or more electrostatic lenses may be used. Four or more electromagnetic lenses may be used as the focus correcting lenses.

For example, currents are passed through a plurality of loops such that the sum of currents in the rotation direction surrounding the optical axis is zero. In this case, a table that defines currents to be passed through a plurality of loops for satisfying a non-rotating condition, a condition under which the virtual crossover CO2 as viewed from the downstream side is unchanged, and an in-focus condition is determined in advance and stored in the memory 68. The lens control circuit 66 refers to the table stored in the memory 68 and controls the amount of current in the plurality of loops on the basis of the surface height of the sample 44 to perform focus correction (dynamic focusing).

As illustrated in FIG. 5, the focus correcting lenses may include antisymmetric magnetic tablet lenses 70, cylindrical electrodes 72 each surrounding the axis of the antisymmetric magnetic tablet lenses 70 and disposed in such a way that the center position thereof in the front-to-back direction coincides with the center position of the corresponding antisymmetric magnetic tablet lens 70, and ground electrodes 74. Each arrow in FIG. 5 is an example of the direction of a magnetic field. Magnetic fields in opposite directions are alternately produced. Although four focus correcting lenses are installed in FIG. 5, five or more focus correcting lenses may be used.

Applying voltages to the electrodes 72 changes the energy of electrons, and changes the focal length and the amount of rotation of the lenses accordingly. All voltages applied to the four electrodes 72 are changed to satisfy the non-rotating condition and the condition under which the virtual crossover CO2 as viewed from the downstream side is unchanged. Voltages applied to the electrodes 72 and satisfying a non-rotating condition, a condition under which the virtual crossover CO2 as viewed from the downstream side is unchanged, and an in-focus condition are determined in advance, and a table that defines the voltages is stored in the memory 68. The lens control circuit 66 refers to the table stored in the memory 68, and controls the voltage applied to each electrode 72 on the basis of the surface height of the sample 44 to perform focus correction (dynamic focusing).

When the magnetic field of an electromagnetic lens is present on the sample surface, incident electrons, which have a velocity in the rotation direction, are generally incident on the sample surface at an angle in the rotation direction. Therefore, when a magnetic field cancelling lens having an excitation direction opposite that of the second objective lens 30 is disposed below the XY stage 42 (on the downstream side in the beam propagation direction) to cancel out the magnetic field on the sample surface, and then an objective lens configured to eliminate the inclination of the rotation direction is used, it is possible to suppress variation in the rotation direction of the beam incident position associated with variation in the sample surface height.

In the embodiment described above, non-rotating lenses are used as the focus correcting lenses. However, the rotation angle condition for the focus correcting lenses is not limited to a non-rotating condition, and rotation correction may be performed.

When four or more electromagnetic lenses are used, it is possible to correct the focus while satisfying a condition under which the virtual crossover CO2 as viewed from the downstream side is unchanged and correct the rotation angle. A current to be passed through each electromagnetic lens for satisfying a condition under which the virtual crossover CO2 as viewed from the downstream side is unchanged, a condition of the amount of rotation, and an in-focus condition, is determined in advance and a table defining the currents determined is stored in the memory 68. The lens control circuit 66 refers to the table stored in the memory 68 to control the current for the electromagnetic lens on the basis of the surface height of the sample 44 and perform rotation correction together with focus correction (dynamic focusing).

Although the configuration of the multi-beam writing apparatus has been described in the embodiment, the present invention is also applicable to other multi-beam irradiation apparatuses, such as multi-beam inspection apparatuses. The present invention is applicable not only to the case of using multiple beams, but also to the case of using, for example, a single variable shaped beam. When positional displacement caused by the Coulomb effect is to be corrected with a variable shaped beam, a bean current can be determined from beam dimensions.

The same or similar effect can be achieved when focus correcting lenses are arranged to sandwich the conjugate point of the crossover on the upstream side, not the crossover position on the most downstream side. In this case, the actual crossover is unchanged downstream of the focus correcting mechanism.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi charged particle beam irradiation apparatus comprising:
a charged particle source configured to generate and emit multiple beams;
an optical system including a plurality of lenses configured to adjust the multiple beams emitted from the charged particle source; and
a lens control circuit configured to control the plurality of lenses,
wherein the optical system is configured such that a virtual crossover as viewed from a downstream side of the multiple beams is formed in an anterior focal plane of an objective lens being a lowermost lens of the plurality of lenses, the anterior focal plane being located opposite a sample surface with respect to the objective lens, and that the multiple beams passed through the objective lens are perpendicularly incident on the sample surface;
the plurality of lenses include three or more focus correcting lenses configured to perform focus correction of the multiple beams in accordance with a height of the sample surface and/or beam current;
an actual crossover (CO2r) is located between a principal surface of an uppermost focus correcting lens of the three or more focus correcting lenses and a principal surface of a lowermost focus correcting lens of the three or more focus correcting lenses; and
the lens control circuit is configured to control a voltage applied to or a current passed through each of the focus correcting lenses such that a predetermined rotation angle condition, a condition under which a virtual crossover (CO2) as viewed from the downstream side is unchanged, and an in-focus condition are satisfied.

2. The multi charged particle beam irradiation apparatus according to claim 1, further comprising a memory configured to store a table that defines voltages applied to, or currents passed through, the focus correcting lenses and satisfying the predetermined rotation angle condition, the condition under which the virtual crossover as viewed from the downstream side is unchanged, and the in-focus condition,
wherein the lens control circuit is configured to refer to the table and control the voltage applied to or the current passed through each of the focus correcting lenses on the basis of the height of the sample surface.

3. The multi charged particle beam irradiation apparatus according to claim 1, wherein the three or more focus correcting lenses are non-rotating lenses.

4. The multi charged particle beam irradiation apparatus according to claim 3, wherein the non-rotating lenses are electrostatic lenses.

5. The multi charged particle beam irradiation apparatus according to claim 3, wherein the optical system includes four or more focus correcting lenses; and
the non-rotating lenses are non-rotating electromagnetic lenses formed by current loops of equal magnitude in opposite directions.

6. The multi charged particle beam irradiation apparatus according to claim 3, wherein the optical system includes four or more focus correcting lenses; and
the non-rotating lenses are non-rotating electromagnetic lenses in which currents are passed through a plurality of loops such that a sum of currents in one rotation direction surrounding an optical axis is zero.

7. An adjusting method of a multi charged particle beam irradiation apparatus, the adjusting method comprising:
adjusting, in the multi charged particle beam irradiation apparatus according to claim 1, a focal length of the focus correcting lenses while a magnification variation of a distribution of the multiple beams is kept smaller than an allowable variation.
